(19) United States
(12) Patent Application Publication
(10) Pub. No.: US 2026/0271624 A1
(43) Pub. Date: Sep. 10, 2026

(54) PRECISE SPATIAL PHOTODOPING OF LATERAL GRAPHENE INTERFACES

(71) Applicants: University of Maryland, College Park, College Park, MD (US); William Marsh Rice University, Houston, TX (US); Government of the United States of America, as represented by the Secretary of Commerce, Washington, DC (US); The Government of the United States as represented by the Director, National Security Agency, Fort George G. Meade, MD (US)

(72) Inventors: Son Truong Le, Ellicott City, MD (US); Thuc T. Mai, Dayton, OH (US); Maria F. Munoz, Gaithersburg, MD (US); Angela R. High Walker, Gaithersburg, MD (US); Curt A. Richter, Gaithersburg, MD (US); Aubrey T. Hanbicki, College Park, MD (US); Adam L. Friedman, College Park, MD (US)

(73) Assignee: University of Maryland, College Park, College Park, MD (US)

(21) Appl. No.: 19/252,286

(22) Filed: Jun. 27, 2025

Related U.S. Application Data
(60) Provisional application No. 63/664,912, filed on Jun. 27, 2024.

(51) Int. Cl. H10N 52/01; H10N 50/85; H10N 52/00

(52) U.S. Cl. CPC H10N 52/01; H10N 50/85; H10N 52/101

(57) ABSTRACT

Semiconductor devices and methods of doping. The methods include providing a first insulating layer, a second insulating layer, and a semiconductor layer disposed between the first insulating layer and the second insulating layer. The methods include biasing the semiconductor layer and irradiating the first insulating layer, the semiconductor layer and the second insulating layer with an irradiation source.

### GOVERNMENT LICENSE RIGHTS

This invention was made with government support under H98230-19-C-0220 awarded by the National Security Agency and under 70NANB16H240 awarded by the National Institute of Standards and Technology. The government has certain rights in the invention.

### TECHNICAL FIELD

The present disclosure relates generally to photodoping of semiconductors, and more particularly to precise spatial photodoping.

### BACKGROUND

A central component and crucial ingredient of all integrated circuits is doped semiconductors. As feature sizes shrink with the continual march toward smaller integrated circuit nodes, accurate spatial doping of semiconductors becomes more challenging.

### SUMMARY

Existing challenges associated with the foregoing, as well as other challenges, are overcome by the presently disclosed semiconductor devices and methods of doping. One embodiment of the present disclosure is a method of doping that includes providing a first insulating layer, a second insulating layer, and a semiconductor layer disposed between the first insulating layer and the second insulating layer. The methods include biasing a back gate while keeping the semiconductor layer grounded and irradiating the first insulating layer, the semiconductor layer and the second insulating layer with an irradiation source.

In aspects, the semiconductor layer is a Van der Waals (vdW) semiconductor layer.

In aspects, the first insulating layer is a Van der Waals (vdW) insulating layer.

In aspects, the second insulating layer is a Van der Waals (vdW) insulating layer.

In aspects, the semiconductor layer is graphene.

In aspects, the first insulating layer is hexagonal boron nitride.

In aspects, the second insulating layer is hexagonal boron nitride.

In aspects, one or more remote dopants are created in at least one of the first insulating layer or the second insulating layer.

In aspects, the method further includes applying a second bias to a back gate with the semiconductor layer grounded and applying the irradiation source to the first insulating layer, the semiconductor layer and the second insulating layer.

In aspects, the method further includes applying a zero volt voltage to a back gate with the semiconductor grounded and reapplying the irradiation source to the first insulating layer, the semiconductor layer and the second insulating layer to set the doping level back to an original value and applying a second bias voltage to the back gate with the semiconductor grounded and applying the irradiation source to the first insulating layer, the semiconductor layer and the second insulating to set a new doping level.

In aspects, a mobility of the semiconductor layer is increased, and remote dopants are generated within the first insulating layer, the semiconductor layer and the second insulating layer.

In aspects, the remote dopants provide protection for conducting carriers from fictitious scattering and enhance their mobility in the semiconductor channel.

In another embodiment, a doped device includes a first insulating layer, a second insulating layer, and a semiconductor layer disposed between the first insulating layer and the second insulating layer. A bias is applied to a back gate with the semiconductor layer grounded and an irradiation source is applied to the first insulating layer, the semiconductor layer and the second insulating layer.

In another embodiment, a device including a first Van der Waals (vdW) insulating layer, a second Van der Waals (vdW) insulating layer, and a Van der Waals (vdW) semiconductor layer disposed between the first vdW insulating layer and the second vdW insulating layer. A bias is applied to a back gate the vdW semiconductor conduction channel is grounded, and an irradiation source is applied to the first vdW insulating layer, the vdW semiconductor layer and the second vdW insulating layer to generate remote dopants for the vdW semiconductor conduction channel.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 illustrates a system for photodoping semiconductors in accordance with the present disclosure;

FIG. 2 illustrates channel resistance, R_{XX}, plotted vs back gate voltage V_{BG} (voltage 60) from a series of global doping exams in accordance with the present disclosure;

FIG. 3 illustrates Rₓₓ, as a function of back gate voltage, V_{BG}, after the local region of the sample was subjected to photodoping with V_{BG}=V_{D-L}=−18 V in accordance with the present disclosure;

FIG. 4 illustrates a 2D map of channel resistance, R_{XX}, vs back gate voltage, V_{BG}, and local doping voltage, V_{D-L} in accordance with the present disclosure;

FIG. 5 illustrates the quantum Hall effect in a device uniformly doped at V_{D-G}=0 V, as a function of back gate voltage, V_{BG} in accordance with the present disclosure;

FIG. 6 illustrates the quantum Hall response of a sample, at 9 T, after a local doping configuration with V_{D-L}=−24 V, in accordance with the present disclosure; and

FIG. 7 illustrates a Landau fan diagram after the sample was locally doped at V_{D-L}=−24 V showing the appearance of an insulating state when the sample is in p-n-p doping configuration, in accordance with the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

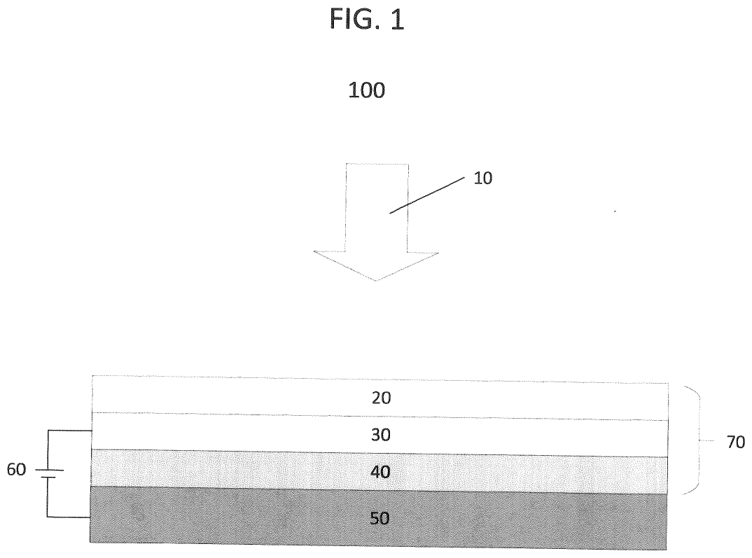

FIG. 1 illustrates a system for photodoping semiconductors, arranged in accordance with at least some embodiments described herein. System 100 includes an irradiation source 10, a first insulating layer 20, a semiconductor layer 30, a second insulating layer 40, and a back gate substrate 50. Irradiation source 10 may be any energy source, including an electron beam, ion beam, laser beam, an LED white-light illuminator, colored LED, incandescent illuminator or any other illumination source.

First insulating layer 20 may be an insulating material utilized in CMOS (Complementary Metal-Oxide-Semiconductor) transistors such as bulk dielectric materials like SiO₂, HfO₂, Al₂O₃ etc. and may include Van der Waals (vdW) insulators. First insulating layer 20 may include hexagonal boron nitride (hBN), calcium hydroxide, magnesium hydroxide, chromium germanium telluride, molybdenum trioxide, and Mika etc. Semiconductor layer 30 may be a conventional semiconductor material like Silicon or Germanium, and may include Van der Waals (vdW) semiconductors such as transition metal dichalcogenides (TMDs) semiconductor materials, graphene, black phosphorous, indium selenide etc. Second insulating layer 40 may be an insulating material utilized in CMOS transistors such as bulk dielectric materials like SiO₂, HfO₂, Al₂O₃ etc. and may include Van der Waals (vdW) insulators. Second insulating layer 40 may include hexagonal boron nitride (hBN) calcium hydroxide, magnesium hydroxide, chromium germanium telluride, molybdenum trioxide, and Mika etc. First insulating layer 20, semiconductor layer 30, and second insulating layer 40 may form a semiconducting device 70.

Back gate substrate 50 may be a substrate gate or a bottom gate and may be a conductive layer. Back gate substrate 50 may be silicone. In an embodiment, back gate substrate 50 may be a heavily doped p+Si substrate and may include a layer of thermally grown SiO₂ on top which may be ~290 nm in thickness.

Semiconductor layer 30 may be doped by optically and/or electrically activating the defect states in first insulating layer 20 and/or second insulating layer 40 and thereby inducing carrier density changes in the 2D material of semiconductor layer 30.

Semiconductor layer 30 may be optically doped by activating defect states including holes in first insulating layer 20 with irradiation source 10 directed at first insulating layer 20 and semiconductor layer 30. Semiconductor layer 30 may be electrically doped by activating defect states including p-type dopants in second insulating layers 20, 40 by biasing semiconductor layer 30 by applying a voltage between semiconductor layer 40 and back gate substrate 50.

A voltage may be applied, and irradiation may be directed to device 70 to cause charged dopants, donors or acceptors, to form remote to the conduction path through semiconductor layer 40.

Voltage 60 may be applied between semiconductor layer 40 and back gate substrate 50. Back gate voltage 60 may be applied at different global doping voltages ranging from V_{D-G}=0 V to V_{D-G}=−36 V in 4 V steps. The position of the Dirac peaks at each V_{D-G} could be accurately determined to be V_{Dirac_x}=V_{Dirac_0}+V_{D-G} where V_{Dirac_0}≈−1.7 V.

Irradiation source 10 may be applied for a period of time to at least a portion of device 70 to dope that portion. The doping level may be controlled by an amount of voltage 60 applied. Accordingly, dopants may be created inside at least one of first insulating layer 20 and/or second insulating layer 40 residing remote to a conductive channel of device 70 as well as doping the conductive channel.

Additional doping levels may be affected by reapplying voltage 60. For example, a different voltage 60 may be applied and irradiation source 10 applied to introduce a different doping level.

The process can be reversed (e.g., erased) by applying a zero-volt gate voltage 60 and reapplying irradiation source 10 to device 70, which may erase optical doping and set the doping level back to an original form.

As long as light is not applied, the doping level within device 70 may remain. In various embodiments, since the charged dopants are separate from the conduction channel of device 70, the mobility of device 70 may be increased since the conduction channel is shielded from carrier scattering and insulated from fictitious substrate scattering.

In an example, a device 70 was fabricated on a heavily doped p+Si substrate with ~290 nm of thermally grown SiO2 on top (back gate substrate 50) with the doped Si used as the back gate. A dry transfer method was used to fabricate and transfer an exfoliated hBN/Gr/hBN heterostructure (first insulating layer 20/semiconducting substrate layer 30/second insulating layer 40) onto a substrate with pre-patterned alignment markers. The graphene (semiconducting substrate layer 30) was a single layer and the thickness of both the top and bottom hBN layers (first insulating layer 20/second insulating layer 40) was ~50 nm. The heterostructure was then patterned into a conventional Hall bar geometry by using electron-beam (e-beam) lithography followed by subsequent reactive ion etching. Care was taken to select an area of the heterostructure that was bubble free (as measured by atomic force microscopy (AFM)) for the Hall bar to achieve the highest device quality. A second e-beam lithography step, followed by the e-beam deposition of Cr/Pd/Au (5 nm/10 nm/75 nm) and subsequent metal lift-off, was used to form 1D metal edge contacts to the hBN-sandwiched graphene (first insulating layer 20/semiconducting substrate layer 30/second insulating layer 40). It is highly likely that different sources of hBN have different defect densities, which play a role in successful doping.

Doping was performed at 1.6 K, the base temperature of the apparatus used to take most of the measurements. However, doping may be performed at room temperature with equal results. Two general doping procedures were performed: Procedure (1) was global doping, with the entire hBN/Gr/hBN (first insulating layer 20/semiconducting substrate layer 30/second insulating layer 40) device 70 doped at the same level, and Procedure (2), local doping. Local doping was performed with a well-focused 633 nm laser, with ~100 μW of laser power, which was used to selectively optically dope only a specific region of the hBN/Gr/hBN device (first insulating layer 20/semiconducting substrate layer 30/second insulating layer 40). The laser wavelength, hence, the photon energy used, may affect the type of defect that is activated in the hBN bandgap.

Procedure (1): A fixed back gate voltage 60, V_{D-G}, was applied while the entire hBN/Gr/hBN (first insulating layer 20/semiconducting layer 30/second insulating layer 40) heterostructure was illuminated with an LED white-light illuminator (irradiation source 10) focused on the sample through a 50× objective. The illumination time was fixed at 10 minutes for each doping level. After the irradiation source was extinguished, the backgated voltage 60 was set to zero to conclude the doping procedure.

Procedure (2): The sample (first insulating layer 20/semiconducting substrate layer 30/second insulating layer 40) was mounted on a magnetic- and cryogenic-safe nano-positioner and positioned at the focus of a 50× objective. To determine the position of the graphene device, a Raman map of the graphene's 2D phonon peak and the Raman signal from the Si substrate were determined. After the Raman map, an initial voltage was set to zero, V_{BG}=0 V, to “clean” the sample of any charge doping inhomogeneity created by the small laser spots during the mapping step. Then, a fixed back gate voltage, V_{D-L}, was applied while a portion of the graphene heterostructure (first insulating layer 20/semiconducting substrate layer 30/second insulating layer 40) was illuminated with a 633 nm laser focused through the same 50× objective. Specifically, the sample was rastered relative to the fixed laser position over a locally defined region for 10 minutes for each doping level (i.e. back gate voltage). At best, the laser spot size is diffraction limited, with a Gaussian intensity profile of approximately 1 micron in diameter. After the irradiation source 10 was extinguished, the back gate voltage was set to zero to conclude the doping procedure.

Magnetotransport measurements were performed on the example samples at 1.6 K with magnetic fields between 0 T and 9 T applied out-of-plane to verify functionality and quantify the doping properties of the sample examples. All sample examples were only illuminated during the doping processes and during transport measurements, irradiation source 10 and any other illumination sources (white light illuminator or laser) were off. Traditional lock-in amplifier techniques were used with currents ranging from 5 nA to 100 nA at 19 Hz. The estimated mobility was ~100,000 V cm−2 s−1 at 1.6 K for a carrier density of 1×1012 cm−2 determined from a conventional Drude model. The longitudinal resistance (R_{XX}) and Hall conductance (G_{XY}) were measured as a function of applied back gate voltage (V_{BG}), global (V_{D-G}) and local (V_{D-L}) doping voltages, and applied magnetic field, B. After each transport measurement, regardless of whether the example sample was locally or globally doped, each example sample was illuminated with white light overnight with an applied V_{D-G}=0 V. This acted as a “reset” for the example sample to erase previous doping configurations and restore the example device to its original response. For all of the doping experiments presented in the main text, negative V_{D-G} or V_{D-L} values were used. The doping technique also works with positive V_{D-G} Or V_{D-L} values.

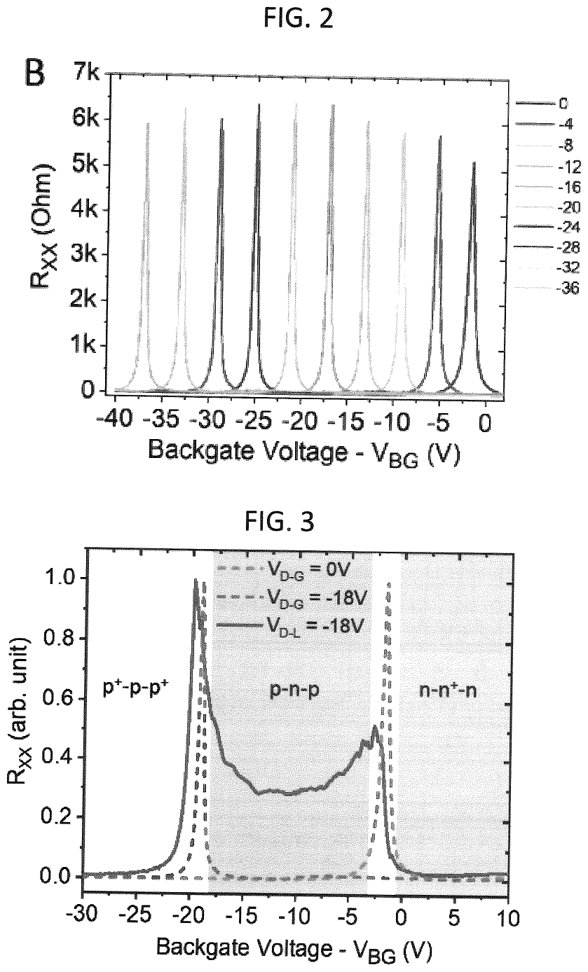

FIG. 2 illustrates channel resistance, R_{XX}, plotted vs back gate voltage V_{BG} (voltage 60) from a series of global doping examples. In this sequence, Procedure (1) was repeated at different values of V_{D-G} from 0 V to −36 V at 4 V incremental steps. The response at V_{D-G}=0 V is used as the baseline value and is used to compare all other doping levels. The baseline graphene Dirac point is V_{Dirac}_0≈−1.7 V, and this value stayed constant over the course of the experiment duration of ~3 months. The position of the Dirac point after illumination while a given global voltage, V_{D-G}=x, is simultaneously applied is V_{Dirac_x}=V_{Dirac_0}+V_{D-G}, is determined by the doping level.

It is clear from the data that the ultimate doping level can be set solely by the V_{D-G}. We determine the n-doping level in the sample for each V_{D-G} which ranged from ~5×1010/cm2 at V_{D-G}=0 to ~2×1012/cm2 at V_{D-G}=−36 V. The remarkable series of peaks shown in FIG. 2 illustrates the precise doping control that can be achieved for each V_{D}-G. This determination of the V_{Dirac_x} as proportional to doping level allows for reproducibly tuning of the global doping level in a device with very high precision and dynamic range.

An arbitrary area may be doped with the laser-based local doping approach described in Procedure (2). In examples, a simple geometry was chosen to demonstrate the method. As with global doping, the doping level of the locally illuminated area was determined by the value of V_{D-L}, while the rest of the sample was determined to have no doping change. In FIG. 3 the solid curve is channel resistance, Rₓₓ, as a function of back gate voltage, V_{BG}, after the local region of the sample was subjected to photodoping with V_{D-L}=−18 V. A clear indication of successful spatial doping is the emergence of two Dirac peaks in the measurement. One peak, V_{BG}~V_{Dirac_-18}, is the response of the local region and the other is the Dirac peak at V_{BG}~V_{Dirac_0} representing the response of the global region of the sample. To systematically change the doping level in the local region, Procedure (2) was repeated at different V_{D-L}. The overall doping configuration of the sample with respect to the back gate voltage was then changed for each local doping level. In the example shown in FIG. 3 with V_{D-L}=−18 V, from left to right, three shaded areas correspond to p+−p−p+, p−n−p, and n−n+−n, sample doping configurations respectively. For simplicity, these junctions are abbreviated as p+−p−p+=PpP, p−n−p=pnp, and n−n+−n=nNn. Changing the V_{D-L} used in Procedure (2) changed the back gate voltage range where device 70 remained in each of these 3 different doping configurations. For example, with fixed back gate voltage ranging from −40 V to 40 V and with V_{D-L} decreasing to a more negative value, the back gate voltage range where the sample stayed in the pnp doping configuration increased, and the back gate voltage range when the sample stayed in the PpP doping configuration decreased.

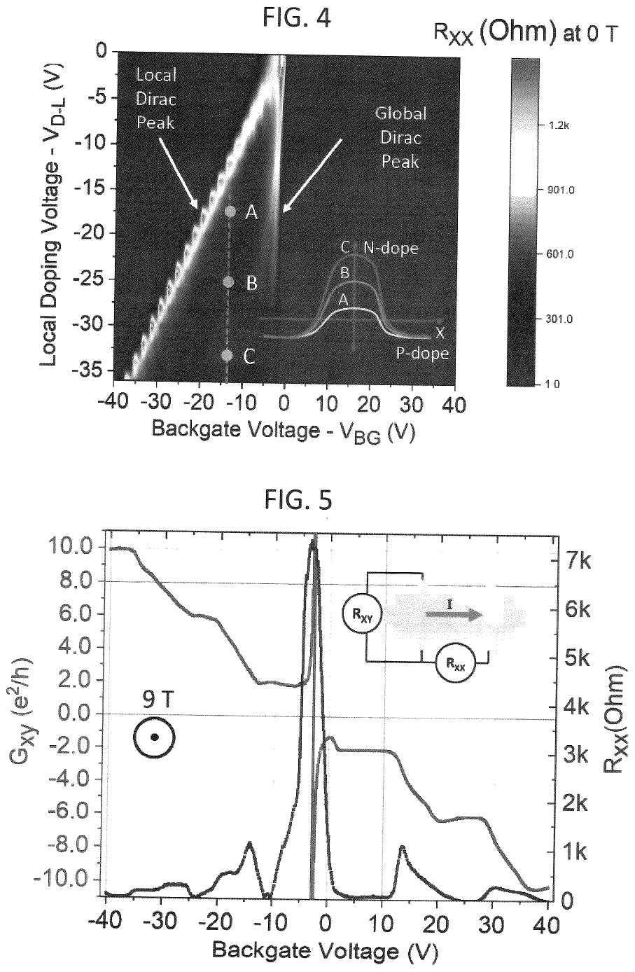

FIG. 4 shows a 2D map of channel resistance, R_{XX}, vs back gate voltage, V_{BG}, and local doping voltage, V_{D-L}. The positions of the Dirac peak are indicated by white arrows with the global Dirac peak on the right and the local Dirac peak on the left. The location of the local Dirac peak evolved linearly with changing V_{D-L}, indicating consistent and accurate doping of the local region over the whole V_{D-L} range. The global Dirac peak remained unchanged, indicating that the doping level of global portion device 70 was not affected by the local doping procedure. Inset shows schematic of the doping distribution along the sample in pnp configuration with respect to different n-doping levels in the local region (different V_{D-L}) at fix back gate bias, point A, B, and C.

Quantum Hall transport measurements were performed on spatially doped junctions after each doping experiment to characterize the doping interfaces. Due to the unique semi-metal properties of graphene that arise from its linear Dirac band structure, pn-junctions (pnJs) in graphene do not exhibit the unidirectional current-blocking behavior at zero magnetic fields associated with traditional pn-diodes. When a strong perpendicular magnetic field is applied to a graphene pn-device, bulk electrons and holes in the p- and n-regions of device 70 are strongly localized by the magnetic field. The example device 70 transport properties are governed by the formation of chiral Landau level (LL) edge-state channels circulating along the boundary and the pnJ interfaces. The LL edge channels circulate in opposite directions for p- and n-regions, resulting in edge states of opposite charge traveling in the same direction, alongside each other, at the electrostatic pnJ interfaces. In the quantum Hall regime, the Hall resistance, R_{XY} is quantized to values of (1/v)(e²/h) where v is an integer, e is the fundamental electron charge, and h is Plank's constant. For graphene, typically, v=±2, ±6, ±10, . . . [²] giving rise to R_{XY} plateaus when v_{G} and v_{L}, the filling factors in the global and local regions, respectively, are near these integer values. v_{G} and v_{L} are determined by the carrier concentration in the global and local regions, respectively, divided by the density of carriers per LL which depends on the applied magnetic field. When these characteristic quantum Hall resistance plateaus are observed the longitudinal resistance R_{XX} is simultaneously 0Ω. Previous quantum Hall measurements of graphene pnJ devices showed that LL interactions at the pnJ interfaces can be used to characterize the electrostatic profile of the pnJ. We used similar measurement and analysis methods here to characterize the pnJs created with the spatially resolved photodoping technique.

FIG. 5 illustrates the quantum Hall effect in device 70 uniformly doped at V_{D-G}=0 V (so that the position of the Dirac point is at V_{Dirac_0}) following Procedure (1), as a function of back gate voltage, V_{BG}. The inset in FIG. 5 shows a schematic of the measurement configuration. The first curve (starting at −40, −11.0) is the longitudinal resistance, R_{XX}, with values shown on the right y-axis. The second curve is the Hall conductance, G_{XY}, in units of e2/h, with values shown on the left y-axis. The example device 70 shows a clear quantum Hall response at 9 T where the quantized Hall conductance at values of ±2e2/h, ±6 e2/h, and ±10 e2/h are observed. Positive values are observed for electrons and negative values for holes, consistent with the measurement, configuration and direction of the magnetic field. R_{XX} is zero at the quantized nodes in the Hall conductance. This quantum Hall response agrees with previous measurement of similar heterostructures. These measurements may be used to determine the filling factors of device 70.

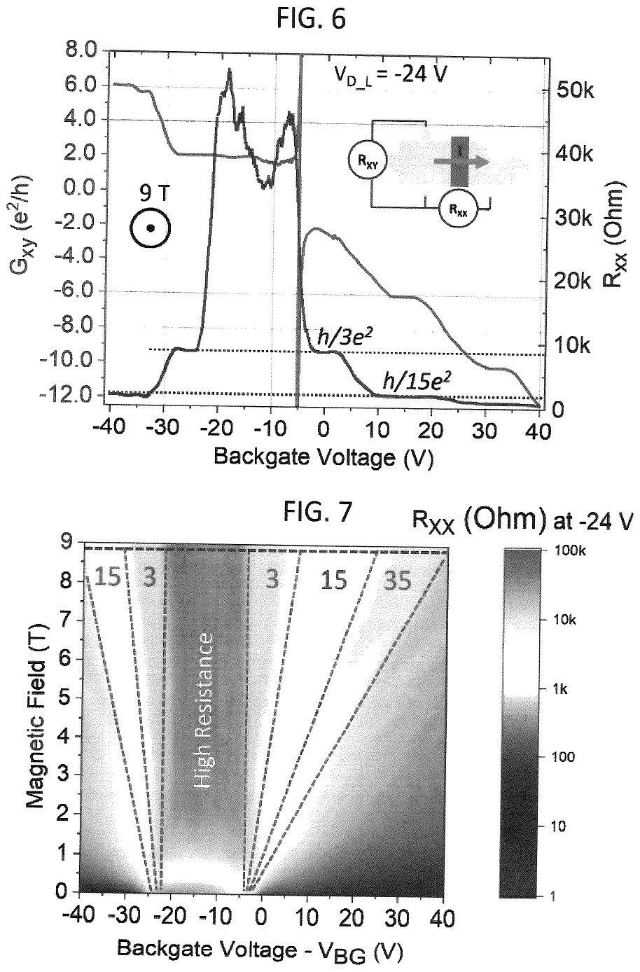

FIG. 6 shows the quantum Hall response of the sample, at 9 T, after Procedure 2 was used to create a local doping configuration with V_{D-L}=−24 V. The position of the locally doped region is indicated by the shaded area in the measurement schematic inset of FIG. 6. The two horizontal dashed lines in FIG. 6 highlight two resistance plateaus in R_{XX}. For the region of device 70 outside of the locally doped region, the doping level remains unchanged at V_{D-G}=0V. Besides the regular quantized conduction plateaus in the Hall conductance, the dominant feature of this measurement is the appearance of unconventional quantized resistance values of h/3e2, h/15e2, and ≈h/35e2 in R_{XX}. These quantized resistance steps in R_{XX} only occur when the sample is in the PpP and nNn doping configurations which arise when V_{BG}<−24 V and V_{BG}>−1.7 V, respectively.

To further elucidate the magnetotransport properties of device 70 in the spatial doped configuration, full Landau fan diagram measurements were performed. In these measurements, the resistance of the example device 70 was measured as a function of V_{BG} and magnetic field. FIG. 8 shows the Landau fan diagram at V_{D-L}=−24 V. The horizontal dashed line near the top is the profile cut of the data shown in FIG. 6. The angled dashed lines are a guide for the eye, separating regions of the resistance steps that have different quantized values. The numbers between the lines are the respective filling factors of each region. Noticeably, the area in the middle of the figure, in the range of −1.7 V<V_{BG}<−24 V, is a high resistance (insulating) state of the example sample where the doping configuration is PnP. This insulating behavior persisted as long as the example sample was in the quantum Hall regime down to B ~1 T. At lower field, when the example sample was not in the quantum Hall regime, the insulating state disappeared. In the high resistance state, the resistance value of the example device 70 was as high as ~100 kOhm and did not show any well-defined resistance quantization indicative of quantum Hall conduction. This “insulating” state is not common and has not been observed in previous transport measurements of graphene pnJ devices in high magnetic fields. To the left of the high resistance region of the magnetoresistance plot, the sample doping is PpP, and to the right of the high resistance area, the sample is doped nNn.

In quantum Hall devices with a differently doped region that extends across the entire width of the sample such as the example sample, the resistance measured across the “barrier” region can depend strongly on the details of the coupling or equilibration between the various LL edge states. In previous examples produced by using graphene pnJ devices created by conventional lithographically patterned gate structures, two distinctive LL edge state equilibration regimes were realized: (i) full equilibration of LL edge states at the pnJ interface, and (ii) lowest LL edge state equilibration at the pnJ interface. Theoretical calculations indicate electrostatically sharp junctions where the transition between the differently doped regions is spatially abrupt enable full equilibration while a more gradual spatial transition in an electrostatically graded junction promotes lowest LL equilibration. The quantum Hall transport of the pnJs in spatially photodoped device 70s is therefore an important tool to identify the electrostatic profile of the transition between locally doped regions.

To better understand the quantum Hall response of the example device 70, experimental results were compared with calculations based upon the well-known Landauer-Biittiker edge state formalism. In order to carry out this comparison, the expected quantized resistance values were calculated with respect to different doping configurations and quantized filling factors.

Doping type and qualitive levels can be determined by the position of the Dirac peak in the global/local region relative to the position of the Fermi level which is set for by the back gate. For example, in the left side the back gate range of the R_{XX} resistance maps identified on the left side in FIG. 3 and shown in FIG. 5 and FIG. 6, the example device 70 is in a unipolar PpP doping configuration. Device 70 is p-type in both the global and local regions with the doping level (filling factor) higher, P, in the global region relative to the doping level (filling factor) in the local region, p. In this gating range, v_{G}>v_{L}. The current flow can be envisioned in this model as follows. When the chiral edge current is incident on the locally p-doped region, the lower index LL's corresponding to the more lightly doped local region flow unimpeded into the locally doped region; however, the higher LL's cannot transmit into the locally doped region as no states are available. These states will scatter at the interface between the local and global regions and cross the sample to the other edge where they reverse direction and are effectively backscattered. On the far side of the local region, all the current in the populated edge states can continue into the more heavily doped global region and continue to the other current contact.

For this unipolar PpP doping configuration values the observed quantized RXX resistance plateaus can be calculated within the Landauer-Buttiker edge state formalism.

$${R}_{xx} = \frac{h}{{e}^{2}} \frac{{ν}_{G} - {ν}_{L}}{{ν}_{G} {ν}_{L}} \qquad ( 1 )$$

Similarly, for the unipolar nNn doping configuration, corresponding to the right side of the back gate range in a magnetoresistance plot or map (indicated on the right in FIG. 3), device 70 has n-type doping in both the global and local regions. The doping level (filling factor) in the global region is lower than the doping level (filling factor) in the local region such that |v_{L}|>|v_{G}|. In this configuration all the chiral edge current incident on the more heavily n-doped local region will transmit into this locally doped region. It has been experimentally observed that in the integer quantum Hall regime, current rapidly equilibrates across all available LL edge states in graphene devices along mechanically etched edges. Therefore, once in the locally doped region, the current will rapidly redistribute across the available edge channels. When these chiral edge states reach the far interface between the local and global regions, the higher LL's cannot transmit out of the locally doped region as no states are available in the global region. Just as described above, these states will scatter at the interface between the local and global regions and cross the sample to the other edge where they reverse direction within the local region. The quantized R_{XX} resistance plateaus calculated in the quantum Hall regime within the Landauer-Buttiker edge state formalism for this unipolar nNn doping are,

$${R}_{xx} = \frac{h}{{e}^{2}} \frac{\vert {ν}_{L} \vert - \vert {ν}_{G} \vert}{\vert {ν}_{G} {ν}_{L} \vert} . \qquad ( 2 )$$

The calculated quantized R_{XX} values for both the unipolar PpP and nNn doping conditions match the experimental values reported in the 2D resistance maps shown in FIG. 6. These “unconventional”, quantized values of R_{XX} and the quantitative agreement with a simple edge-state model provides strong evidence of the promising capabilities of this optical doping method. The technique has both excellent electronic and spatial control of the doping properties of the 2D graphene device. The agreement between the model and the measured data is only possible when the locally doped region completely crosses the full width of device 70 and there are good interfaces between the local and globally doped regions.

The quantized resistance values measured across the “barrier” region can depend strongly on the details of the equilibration between the various LL edge states as they travel along the interface between the two differently doped regions. However, for the PpP and nNn unipolar cases just discussed, where resistance plateaus are observed in R_{XX}, the mechanism of quantized resistance plateau formation can be explained by using the Landauer-Biittiker edge state formalism with no assumptions regarding the interaction of the edge-states at the interfaces between the two doping regions. The LL edge states that can be accommodated in the lower carrier density region circulate the entire device 70 passing through both the global and local regions. Additional edge states arise in the higher carrier concentration regions that do not cross the doping interfaces and circulate only in the regions of higher filling factors.

In the case of a bipolar regime, or pnp doping, corresponding to the middle part of the back gate bias region (shown in FIG. 3, middle area), the LL edge-states in the p- and n-regions circulate in opposite directions in the global and local doping regions. Therefore, they travel alongside each other in the same direction along the left and right interfaces between the global and local regions. It was previously confirmed that in such a case, depending on the electrostatic profile of the pnJs, there could be at least two possible ways the p- and n-LL edge states could interact with each other across the pnJ interfaces. Quantized resistance values for the longitudinal resistance can be calculated according to Landauer-Biittiker edge-state formalism for each of these two cases. In one case, the current equilibrates among all the edge channels on both sides of the interface between the global and local regions, and, in the other case, only the lowest LL exchanges current across the interface.

Case (1): The p- and n-LL edge states completely equilibrate across the pnJ interfaces allowing all LL edge states to participate in conducting current across device 70 from source to drain. The longitudinal resistance in the integer quantum Hall regime with full equilibration, p-doped in the global region with filling factor of □G and n-doped in local region with filling factor of v_{L} is given by:

$${R}_{xx} = \frac{h}{{e}^{2}} \frac{\vert {ν}_{L} \vert + \vert {ν}_{G} \vert}{\vert {ν}_{G} {ν}_{L} \vert} . \qquad ( 3 )$$

Case (2): Only the lowest LL edge states are equilibrated across the pnJ interfaces to conduct current across the regions. All the higher LL edge states are not equilibrated with the lowest LL edge state and backscatter across the sample at the pnJ interfaces. The longitudinal resistance with partial equilibration, p-doped in the global region with filling factor of v_{G} and n-doped in local region with filling factor of v_{L}, lowest LL edge state with filling factor of v₀=2 is given by:

$${R}_{xx} = \frac{h}{{e}^{2}} \frac{3 \vert {ν}_{G} \vert - \vert {ν}_{0} \vert}{\vert {ν}_{G} {ν}_{0} \vert} \qquad ( 4 )$$

The measured resistance values of device 70 when it is in the pnp doping configuration in the quantum Hall regime, shown in FIG. 5 and FIG. 6, do not match the values predicted by either of these two LL edge state interaction models. Quantized conduction is not observed, and the resistance values are much higher than the expected values according to the models for any filling factor. This high resistance is indicating that the central n-doped region is acting to block the current in this device 70 configuration.

It has been previously shown that the electrostatic profile of the pnJs plays a crucial role in determining the interaction between n- and p-LL edge states at the pnJ interfaces. In physically abrupt or sharp pnJ interfaces the p- and n-LL edge states in are close proximity to each other as they travel alongside each other at the pnJ interfaces. This proximity enables the scattering of carriers between the edge states and the equilibration of the chemical potential all of the LL's edge states participate in conducting current across the pnJs. Alternatively, in a more graded junction, where the n- and p-LL's level edge states are physically further apart as they travel along the doping interfaces, only the energetically lowest n- and p-LL's edge states interact. This physical separation results in a partial equilibration of the LL's edge states across the junction. Due to the nature of the optical doping technique, we expect it will create graded pnJ junctions. In the best-case scenario, the Gaussian intensity profile of the laser beam creates a doping region with edges that diminish as 1/e², over approximately 1 um. This optical gradient implies that the pnJs formed are gradually graded compared to conventional gate-defined pnJs.

The spatial photodoping profile of an hBN/Gr/hBN heterostructure was previously inferred by gradually extending the local doping region between two voltage probes of device 70 while monitoring the evolution of the Dirac peaks. This method, while given an indication of successful spatial doping, does not provide detailed information on the quality of doping profile of the whole device 70 nor how complete the doping boundary is across the width of the sample. Also, the estimation of the spatial electrostatic profile of the doping interface is limited by the physical dimensions and geometry of the voltage probes as well as the alignment of the laser with respect to these voltage probes.

The quantum Hall measurement indicates that there is little or no interaction between the LL edge states between the p-region (global region) and the n-region (local region) and there is no complete transmission of any LLs, not even the energetically lowest. Device 70 is in a current-blocking state at this doping configuration.

To further investigate the highly resistive state of the sample in the pnp doping configuration in the quantum Hall regime we performed extensive doping modification of the local region and measured the respective quantum Hall response after each doping change. The quantum Hall resistance map of R_{XX} vs V_{BG} and local doping gate, V_{D-L} are shown in FIG. 8. The magnetic field was fixed at 9 T. The dashed lines are a guide for the eyes, separating regions of the resistance steps that have different quantized resistance values. The area in the middle of the figure is the high resistance state of the sample where the doping configuration is pnp. To the left of the high resistance area, the sample was in the PpP doping configuration, and to the right of the high resistance area the sample is in the nNn regime. By increasing the n-doping density in the local region, the back gate bias range in which the sample stays in the pnp doping configuration increases and expands towards the negative back gate bias. Regardless of the doping density level in the local region, well-quantized resistance plateaus were observed when the sample is outside of the pnp range and in the PpP and nNn configurations. This quantized behavior confirms that clean and complete interfaces are formed between the local and global region of the sample and are further proof of the repeatability and stability of this doping technique over a large doping range. No quantized resistance plateaus in R_{XX} were observed when the sample was in the pnp doping configuration regardless of the doping density in the local region. R_{XX} consistently stays in the high resistance, current blocking, state throughout the doping range when the example sample is in pnp spatial doping configuration. This observation reinforces that the photodoping technique has created a gradually graded pnJ profile in the example device 70.

The unique electrostatic profile of the pnJ interfaces created by the photodoping gives rise to the novel observed transport behavior that was just described above. Despite excellent electrical properties, graphene lacks a bandgap and associated gate-toggled high and low resistance states. Therefore, practical applications in digital electronic architectures have not been forthcoming. The unique junction profile combined with low quantization B-field requirement of the sample examples could create a high-performance graphene switching device 70 that has a good ON/OFF ratio. In addition, this gradually graded pnJ profile, when also demonstrated in other 2D TMD semiconductors interfaces with hBN, could reveal many other possible applications, such as pnJ light emitting diodes or solar cells.

A device in accordance with the present disclosure may provide a method for precise special photodoping of semiconductors. A device in accordance with the present disclosure may be rewritable when exposed to light. A device in accordance with the present disclosure may utilize activation of defects in an insulating layer to dope a semiconductive substrate.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (e.g., all described acts or events may not be necessary to carry out the techniques). In addition, while certain aspects of this disclosure are described as being performed by a single module or unit for purposes of clarity, it should be understood that the techniques of this disclosure may be performed by a combination of units or modules associated with, for example, the above-described servers and computing devices.

While the description above refers to particular aspects of the present disclosure, it will be understood that many modifications may be made without departing from the spirit thereof. Additional steps and changes to the order of the algorithms can be made while still performing the key teachings of the present disclosure. Thus, the accompanying claims are intended to cover such modifications as would fall within the true scope and spirit of the present disclosure. The presently disclosed aspects are, therefore, to be considered in all respects as illustrative and not restrictive, the scope of the disclosure being indicated by the appended claims rather than the foregoing description. Unless the context indicates otherwise, any aspect disclosed herein may be combined with any other aspect or aspects disclosed herein. All changes that come within the meaning of, and range of, equivalency of the claims are intended to be embraced therein.

What is claimed is:

1. A method for doping, comprising:
providing a first insulating layer;
providing a second insulating layer;
providing a semiconductor layer disposed between the first insulating layer and the second insulating layer;
biasing a back gate while keeping the semiconductor layer grounded; and
irradiating the first insulating layer, the semiconductor layer and the second insulating layer with an irradiation source.

2. The method of claim 1, wherein the semiconductor layer is a Van der Waals (vdW) semiconductor.

3. The method of claim 1, wherein the first insulating layer is a Van der Waals (vdW) insulating layer.

4. The method of claim 1, wherein the second insulating layer is a Van der Waals (vdW) insulating layer.

5. The method of claim 1, wherein the semiconductor layer is graphene.

6. The method of claim 1, wherein the first insulating layer is hexagonal boron nitride.

7. The method of claim 1, wherein the second insulating layer is hexagonal boron nitride.

8. The method of claim 1, wherein one or more remote dopants are created in at least one of the first insulating layer or the second insulating layer.

9. The method of claim 1, further comprising:
applying a second bias to a back gate with the semiconductor layer grounded; and
applying the irradiation source to the first insulating layer, the semiconductor layer and the second insulating layer to change the doping level.

10. The method of claim 1, further comprising:
applying a zero volt voltage to a back gate with the semiconductor layer grounded and reapplying the irradiation source to the first insulating layer, the semiconductor layer and the second insulating layer to set the doping level back to an original value; and
applying a second bias voltage to the back gate with the semiconductor layer grounded and applying the irradiation source to the first insulating layer, the semiconductor layer and the second insulating to set a new doping level.

11. The method of claim 1, wherein a mobility of the semiconductor layer is increased, and remote dopants are generated within the first insulating layer, the semiconductor layer and the second insulating layer.

12. The method of claim 11, wherein the remote dopants provide protection for conducting carriers from fictitious scattering and enhance their mobility in the semiconductor channel.

13. A doped device, comprising:
a first insulating layer;
a second insulating layer; and
a semiconductor layer disposed between the first insulating layer and the second insulating layer;
wherein a bias is applied to a back gate with the semiconductor layer grounded and an irradiation source is applied to the first insulating layer, the grounded semiconductor layer and the second insulating layer.

14. The device of claim 13, wherein the semiconductor layer is graphene.

15. The device of claim 13, wherein the first insulating layer is hexagonal boron nitride.

16. The device of claim 13, wherein the second insulating layer is hexagonal boron nitride.

17. The device of claim 13, wherein one or more dopants are created in at least one of the first insulating layer or the second insulating layer.

18. A device, comprising:
a first Van der Waals (vdW) insulating layer;
a second Van der Waals (vdW) insulating layer; and
a Van der Waals (vdW) semiconductor layer disposed between the first vdW insulating layer and the second vdW insulating layer,
wherein a bias is applied to a back gate while the vdW semiconductor conduction channel is grounded and an irradiation source is applied to the first vdW insulating layer, the vdW semiconductor layer and the second vdW insulating layer to generate remote dopants for the vdW semiconductor conduction channel.

19. The device of claim 18, wherein the remote dopants provide protection from fictitious scattering to carriers in the vdW semiconductor conduction channel.

20. The device of claim 18, wherein:
the first vdW insulating layer is hexagonal boron nitride;
the second vdW insulating layer is hexagonal boron nitride; and
the vdW semiconductor layer is graphene.
